(19) United States
(12) Patent Application Publication
(10) Pub. No.: US 2008/0258942 A1
(43) Pub. Date: Oct. 23, 2008

(54) SIGMA-DELTA MULTIPLIER, PHASE-LOCKED LOOP WITH EXTENDED TUNING RANGE AND METHODS FOR GENERATING RF SIGNALS

(75) Inventor: Tony Gschier, Graz (AT)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES AG, MUNICH (DE)

(21) Appl. No.: 11/738,650

(22) Filed: Apr. 23, 2007

(51) Int. Cl. H03M 7/00; H03L 7/06

(52) U.S. Cl. 341/50; 327/158

(57) ABSTRACT

Embodiments of sigma-delta multiplier, phase-locked loop with extended tuning range and methods for generating an RF signal are generally described herein. Other embodiments may be described and claimed. In some embodiments, a sigma-delta modulator generates an output bit stream based on an input word, multiply logic multiplies values of the output bit stream by a predetermined value, and an offset adder adds the multiplied values of the output bit stream to an offset value for use in generating a divided-frequency signal. The range of values of the input word may be reduced allowing the sigma-delta modulator to operate within a more central portion of its operating range.

### TECHNICAL FIELD

Some embodiments pertain to electronic circuits. Some embodiments pertain to frequency generation. Some embodiments pertain to phase-locked loops (PLLs).

### BACKGROUND

Some conventional frequency generating techniques use PLLs to indirectly generate a radio-frequency (RF) signal. To support frequency tuning with fine resolution, fractional-N sigma-delta PLLs have been employed. One issue with fractional-N sigma-delta PLLs is that over wider frequency ranges, frequency holes and/or spurs appear. These frequency holes and/or spurs negatively affect the performance of receivers and transmitters.

Thus, there are general needs for PLLs that operate over wider frequency ranges and methods for generating frequencies. There are also needs for PLLs that generate frequencies with finer resolution over wider frequency ranges.

### BRIEF DESCRIPTION OF THE DRAWINGS

FIG. 1 is a block diagram of a PLL in accordance with some embodiments of the present invention;

FIG. 2A illustrates outputs of some example signal-delta modulators suitable for use with some embodiments of the present invention;

FIG. 2B illustrates outputs of some elements within a PLL in accordance with some embodiments of the present invention;

FIG. 3 is a block diagram of a wireless communication device in accordance with some embodiments of the present invention; and

FIG. 4 is a procedure for generating an RF signal in accordance with some embodiments of the present invention.

### DETAILED DESCRIPTION

The following description and the drawings sufficiently illustrate specific embodiments of the invention to enable those skilled in the art to practice them. Other embodiments may incorporate structural, logical, electrical, process, and other changes. Examples merely typify possible variations. Individual components and functions are optional unless explicitly required, and the sequence of operations may vary. Portions and features of some embodiments may be included in, or substituted for those of other embodiments. Embodiments of the invention set forth in the claims encompass all available equivalents of those claims. Embodiments of the invention may be referred to herein, individually or collectively, by the term “invention” merely for convenience and without intending to limit the scope of this application to any single invention or inventive concept if more than one is in fact disclosed.

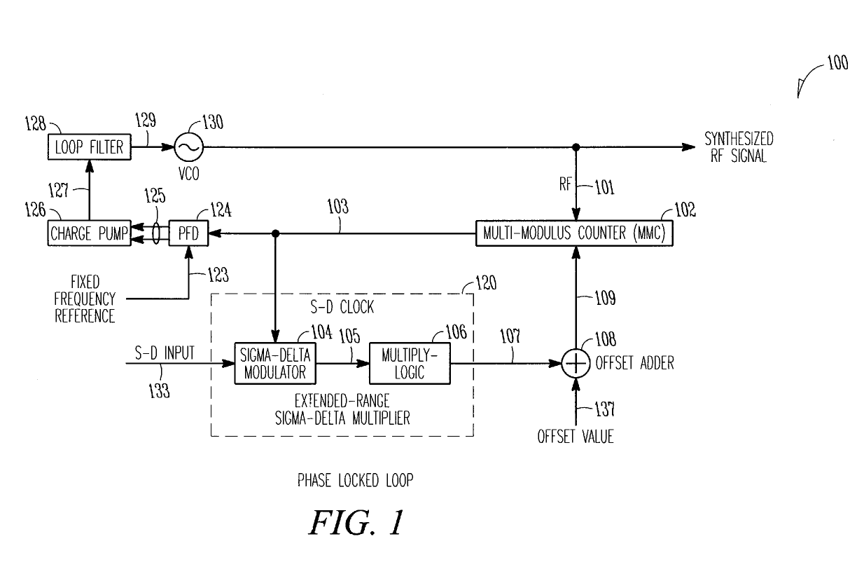

FIG. 1 is a block diagram of a PLL in accordance with some embodiments of the present invention. PLL 100 may have an extended tuning range and may be used to synthesize RF signal 101. PLL 100 may receive offset value 137 to select one of a plurality of frequency bands and may receive input word 133 to tune to a frequency within the selected frequency band. PLL 100 may include extended-range sigma-delta multiplier 120 to generate multiplied values 107 of a bit stream based on input word 133. PLL 100 may also include offset adder 108 to add multiplied values 107 of the bit stream to offset value 137 for use in generating divided-frequency signal 103. As illustrated, extended-range sigma-delta multiplier 120 may include sigma-delta modulator 104 to generate output bit stream 105 based on input word 133, and multiply logic 106 to multiply values of output bit stream 105 by a predetermined value (e.g., two) to generate multiplied values 107.

PLL 100 also includes multi-modulus counter (MMC) 102 to divide RF signal 101 based on value 109 provided by offset adder 108 to generate divided-frequency signal 103. Offset adder 108 may offset multiplied values 107 by offset value 137 to select one of the frequency bands. Changing offset value 137 allows PLL 100 to jump between the frequency bands. Input word 133 may cause PLL 100 to tune to a particular frequency within the selected frequency band.

PLL 100 may also include phase-frequency detector (PFD) 124 to produce control signals 125 based on a phase difference between divided-frequency signal 103 and fixed frequency reference signal 123. PLL 100 may also include charge pump 126 to receive control signals 125 from PFD 124, and loop filter 128 to integrate (e.g., smooth) the output of charge pump 126 to generate control voltage 129. PLL 100 may also include voltage-controlled oscillator (VCO) 130 to generate RF signal 101 based on control voltage 129. Other circuitry may also be included as part of PLL 100.

In some embodiments, PFD 124 may be a phase detector that may control charge pump 126 with control signals 125 to either charge or discharge loop filter 128 by providing input signal 127. Loop filter 128 may integrate input signal 127 to generate control voltage 129. Loop filter 128 may be a low-pass filter. Control signals 125 may comprise pulses having a width proportional to a phase difference between divided-frequency signal 103 and fixed-frequency reference signal 123, although the scope of the invention is not limited in this respect. Fixed-frequency reference signal 123 may be provided by suitable circuitry of a transceiver, such as a baseband processor, although the scope of the invention is not limited in this respect.

In some alternate embodiments, PFD 124 may produce control signals 125 based on a frequency difference between divided-frequency signal 103 and fixed frequency reference signal 123, although the scope of the invention is not limited in this respect. VCO 130 may generate RF signal 101 in response to control voltage 129. VCO 130 may use a crystal oscillator (XOSC) to synthesize RF signal 101.

Multiply logic 106 may be a binary multiplier, and offset adder 108 may be digital offset adder to digitally add the multiplied values of output bit stream 105 to a digital offset value to generate a digital value (i.e., value 109) for use by MMC 102. MMC 102 may divide RF signal 101 by the digital value provided by offset adder 108.

In some embodiments, RF signal 101 may be a carrier-wave (CW) signal have a frequency within the range of approximately 300 MHz to 320 MHz, or approximately 902 to 928 MHz, although the scope of the invention is not limited in this respect as frequencies within other ranges are also suitable. Divided-frequency signal 103 may be a frequency within the range of approximately 10 MHz to 20 MHz, although the scope of the invention is not limited in this respect as frequencies within other ranges are also suitable.

In accordance with some embodiments of the present invention, the range of values of input word 133 may be reduced allowing sigma-delta modulator 104 to operate within a reduced range (i.e., away from its borders). These embodiments are discussed in more detail below. In some embodiments, multiply logic 106 may multiply values of output bit stream 105 by a predetermined value allowing the range of values of input word 133 to be reduced proportionally by the inverse of the predetermined value. This may allow sigma-delta modulator 104 to operate within a more central portion of its operating range. In some embodiments, the range of input word 133 may be halved when multiply logic 106 multiplies the values of output bit stream 105 by two allowing sigma-delta modulator 104 to operate within the central portion of its range. In these embodiments, multiply logic 106 may comprise multiply-by-two logic, although the scope of the invention is not limited in this respect.

In some conventional PLLs, particularly for wider frequency bands, the output of a sigma-delta modulator is shifted by an adder to cover an entire frequency band. At the borders of the operating range of the sigma-delta modulator (i.e., the borders of the input), holes in the frequency band may appear because direct frequency modulation isn't possible. The locations of these holes may be process, temperature, and supply voltage dependent. Another issue with some convention PLLs is that fractional-N spurs increase the closer the inputs of the sigma-delta modulator are to the borders. Embodiments of the present invention include multiply logic 106 allow sigma-delta modulator 104 to operate in a more central portion of its operating range. This may help eliminate holes in the frequency range of PLL 100 and may reduce and/or eliminate fractional-N spurs that are associated with some conventional PLLs.

In some embodiments, sigma-delta modulator 104 generates an output word of output bit stream 105 for each cycle of divided-frequency signal 103. Output bit stream 105 may comprise a pseudo-random sequence having an average value approximately equal to input word 133. Input word 133 may be a binary word having a single value. Output bit stream 105 may comprise fractional output values that are generated by rapidly switching between integer values to provide an average value approximately equal to the value of input word 133, although the scope of the invention is not limited in this respect. Divided-frequency signal 103 may be provided as a clock input of sigma-delta modulator 104. In some embodiments, PLL 100 may be a fractional-N sigma-delta phase-locked loop, although the scope of the invention is not limited in this respect.

In some embodiments, sigma-delta modulator 104 may be a first-order sigma-delta modulator. In other embodiments, sigma-delta modulator 104 may be a second-order sigma-delta modulator. In other embodiments, sigma-delta modulator 104 may be a third-order sigma-delta modulator. In other embodiments, sigma-delta modulator 104 may be a forth or higher-order sigma-delta modulator, although the scope of the invention is not limited in this respect. Some examples of these embodiments are discussed in more detail below.

Although PLL 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, application specific integrated circuits (ASICs), radio-frequency integrated circuits (RFICs) and combinations of various hardware and logic circuitry for performing at least the functions described herein. The functional elements of PLL 100 may refer to one or more processes operating on one or more processing elements.

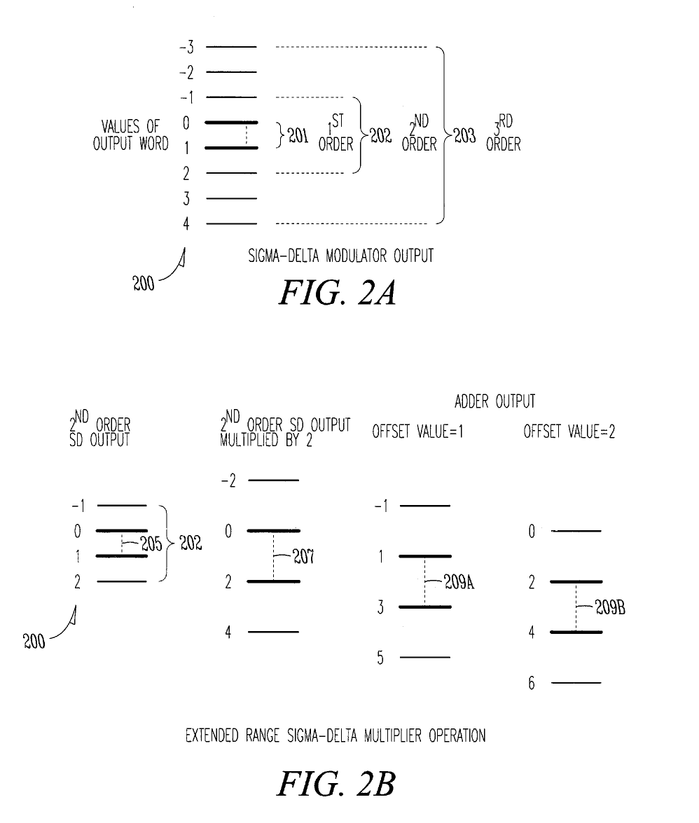

FIG. 2A illustrates outputs of some example signal-delta modulators suitable for use with some embodiments of the present invention. FIG. 2A illustrates output word values 200 for sigma-delta modulators of various orders. For example, when sigma-delta modulator 104 (FIG. 1) is a first-order sigma-delta modulator, it may generate one-bit output words having two possible values 201 (e.g., zero and one). When sigma-delta modulator 104 (FIG. 1) is a second-order sigma-delta modulator, it may generate two-bit output words having four possible values 202 (e.g., negative one, zero, one and two). When sigma-delta modulator 104 (FIG. 1) is a third-order sigma-delta modulator, it may generate three-bit output words having eight possible values 203 (e.g., negative three, negative two, negative one, zero, one, two, three and four). As discussed above, the average value of the output words of sigma-delta modulator 104 (FIG. 1) may be approximately equal to input word 133 (FIG. 1).

In accordance with some embodiments, the range of output word values 200 may be reduced based on the predetermined value used by multiply logic 106 (FIG. 1). For example, when multiply logic 106 comprises multiply-by-two logic, the range of output word may be reduced by half. These embodiments are discussed in more detail below.

FIG. 2B illustrates outputs of some elements within a PLL in accordance with some embodiments of the present invention when sigma-delta modulator 104 (FIG. 1) is a second-order sigma-delta modulator. In these embodiments, when multiply logic 106 (FIG. 1) comprises multiply-by-two logic, output word values 200 may have values 205 within a reduced range rather than values 202 over the full operating range. When the output words are multiplied by multiply logic 106 (FIG. 1), these output words may have values 207 (i.e., averaging between 1 and 2) and may correspond to multiplied values 107 (FIG. 1). When offset adder 108 (FIG. 1) adds an offset value of one to values 207, the output of offset adder 108 (FIG. 1) may have values 209A (i.e., averaging between 1 and 3). When offset adder 108 (FIG. 1) adds an offset value of two to values 207, the output of offset adder 108 (FIG. 1) may have values 209B (i.e., averaging between 2 and 4). Other offset values may be used by offset adder 108 (FIG. 1) to select different frequency bands.

As illustrated in FIG. 2B, the use of multiply logic 106 (FIG. 1) allows sigma-delta modulator 104 (FIG. 1) to operate in a more central portion of is range to generate values 205 allowing sigma-delta modulator 104 (FIG. 1) to operate away from the borders (i.e., away from output values of −1 and +2) corresponding to values 202. Furthermore, PLL 100 (FIG. 1) may operate over an extending tuning range without having to switch between frequency bands.

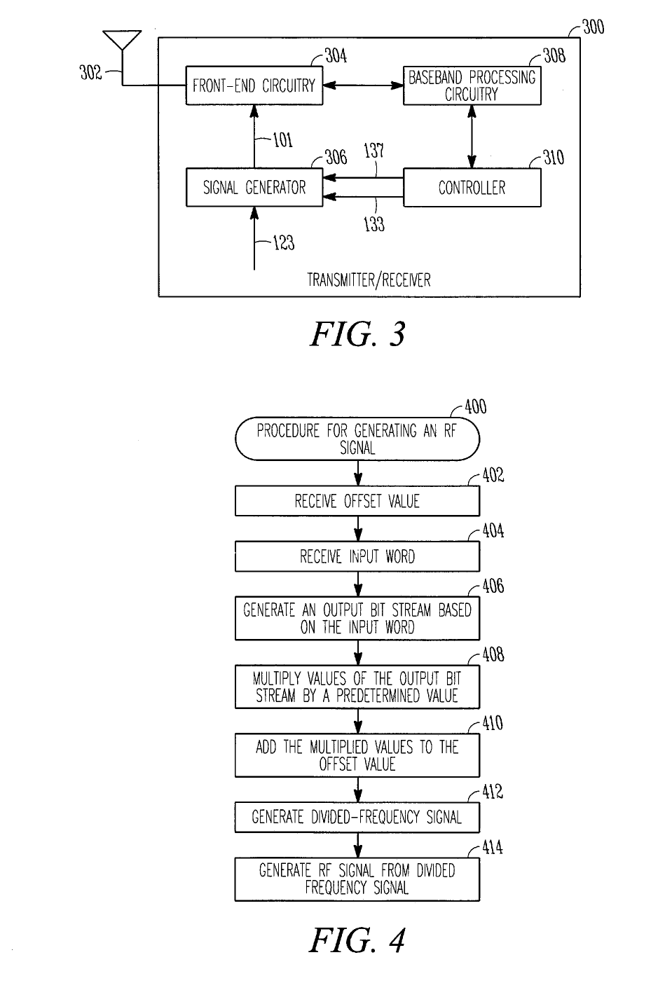

FIG. 3 is a block diagram of a wireless communication device in accordance with some embodiments of the present invention. Wireless communication device 300 may include antenna 302, front-end circuitry 304, baseband processing circuitry, signal generator 306, and controller 310. FIG. 3 may illustrate either the receiver or the transmitter portion of wireless communication device 300.

When wireless communication device 300 operates as a receiver, signals received through antenna 302 may be downconverted by front-end circuitry 304 and processed by baseband processing circuitry 308. Signal generator 306 may generate local-oscillator (LO) signals for use in downconverting and processing the received signals. Controller 310 may select the frequency band and/or particular frequency for generation by signal generator 306.

When wireless communication device 300 operates as a transmitter, signals provided by baseband processing circuitry 308 may be upconverted by front-end circuitry 304 for transmission by antenna 302. Signal generator 306 may generate CW signals for modulation and transmission. Controller 310 may select the frequency band and/or particular frequency for generation by signal generator 306.

In these embodiments, PLL 100 (FIG. 1) may be used as part of signal generator 306. In these embodiments, controller 310 may provide offset value 137 (FIG. 1) to select a frequency band, and input word 133 (FIG. 1) to select a particular frequency with the selected frequency band. In these embodiments, RF signal 101 (FIG. 1) may be used by front-end circuitry 304 for downconverting received signals and/or generating CW signals for transmission.

Although wireless communication device 300 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, application specific integrated circuits (ASICs), radio-frequency integrated circuits (RFICs) and combinations of various hardware and logic circuitry for performing at least the functions described herein. The functional elements of wireless communication device 300 may refer to one or more processes operating on one or more processing elements.

In some embodiments, wireless communication device 300 may be part of a portable wireless communication device, such as personal digital assistant (PDA), a laptop or portable computer with wireless communication capability, a web tablet, a wireless telephone, a wireless headset, a pager, an instant messaging device, a digital camera, an access point, a television, or other device that may receive and/or transmit information wirelessly.

In some embodiments, wireless communication device 300 may communicate in accordance with one or more communication techniques and/or standards. For example, wireless communication device 300 may communicate signals in accordance with the Global System for Mobile Communications (GSM) standard. For example, wireless communication device 300 may communicate signals in accordance with a spread-spectrum technique, such as code division multiple access (CDMA). For example, wireless communication device 300 may communicate signals in accordance with a short-range wireless standard such as the Bluetooth® short-range digital communication protocol. Wireless communication device 300 may communicate signals in accordance with an ultra-wideband (UWB) communication technique where a carrier frequency is not used. For example, wireless communication device 300 may communicate signals in accordance with an optical communication technique, which may be in accordance with the Infrared Data Association (IrDA) standard.

In some embodiments, wireless communication device 300 may include a multicarrier transceiver that may communicate orthogonal frequency division multiplexed (OFDM) communication signals over a multicarrier communication channel. The OFDM signals may comprise a plurality of orthogonal subcarriers. In some of these multicarrier embodiments, wireless communication device 300 may be part of a wireless local area networks (WLANs) communication station such as a wireless access point (AP), base station, or a mobile device including a Wireless Fidelity (WiFi) device. In some of the multicarrier embodiments, wireless communication device 300 may be part of a broadband wireless access (BWA) network communication station, such as a Worldwide Interoperability for Microwave Access (WiMax) communication station, although the scope of the invention is not limited in this respect as wireless communication device 300 may be part of almost any wireless communication device.

In some embodiments, wireless communication device 300 may communicate in accordance with specific communication standards, such as the Institute of Electrical and Electronics Engineers (IEEE) standards including IEEE 802.11(a), 802.11(b), 802.11(g), 802.11(h) and/or 802.11(n) standards and/or proposed specifications for WLANs, although the scope of the invention is not limited in this respect as they may also be suitable to transmit and/or receive communications in accordance with other techniques and standards. Wireless communication device 300 may communicate in accordance with the IEEE 802.16-2004 and the IEEE 802.16(e) standards for wireless metropolitan area networks (WMANs) including variations and evolutions thereof, although the scope of the invention is not limited in this respect as they may also be suitable to transmit and/or receive communications in accordance with other techniques and standards.

Antenna 302 may comprise one or more directional or omnidirectional antennas, including, for example, dipole antennas, monopole antennas, patch antennas, loop antennas, microstrip antennas, or other types of antennas suitable for transmission of RF signals. Instead of two or more antennas, a single antenna with multiple apertures may be used. In these embodiments, each aperture may be considered a separate antenna.

FIG. 4 is a procedure for generating an RF signal in accordance with some embodiments of the present invention. Procedure 400 may be performed by a PLL, such as PLL 100 (FIG. 1), although other configurations of circuitry may also be used to perform procedure 400. Procedure 400 may be used to generate an RF signal, such as RF signal 101 (FIG. 1), in one of a plurality of frequency bands.

Operation 402 comprises receiving an offset value indicating a selected one of a plurality of frequency bands. The offset value may correspond to offset value 137 (FIG. 1).

Operation 404 comprises receiving an input word indicating a frequency within the selected frequency band. The input word may correspond to input word 133 (FIG. 1).

Operation 406 comprises generating an output bit stream based on the input word. Sigma-delta modulator 104 (FIG. 1) may be used to generate output bit stream 105 from input word 133 (FIG. 1).

Operation 408 comprises multiplying values of the output bit stream by a predetermined value. Multiply logic 106 (FIG. 1) may be used to multiply the values of output bit stream 105 (FIG. 1) by a predetermined value, such as two.

Operation 410 comprises adding the multiplied values of the output bit stream to the offset value. Offset adder 108 (FIG. 1) may be used to add multiplied values 107 (FIG. 1) to offset value 137 (FIG. 1) to generate value 109 (FIG. 1).

Operation 412 comprises generating a divided-frequency signal based on the result of operation 410. MMC 102 (FIG. 1) may be used to generate divided-frequency signal 103 (FIG. 1) based on value 109 (FIG. 1) as the output of offset adder 108 (FIG. 1).

Operation 414 comprises generating an RF signal from the divided-frequency signal. RF signal 101 (FIG. 1) may be generated from divided-frequency signal 103 (FIG. 1) using PFD 124 (FIG. 1), charge pump 126 (FIG. 1), loop filter 128 (FIG. 1) and VCO 130 (FIG. 1). The RF signal generated in operation 414 may be used as part of a wireless communication device, such as wireless communication device 300 (FIG. 3).

Although the individual operations of procedure 400 are illustrated and described as separate operations, one or more of the individual operations may be performed concurrently, and nothing requires that the operations be performed in the order illustrated.

Unless specifically stated otherwise, terms such as processing, computing, calculating, determining, displaying, or the like, may refer to an action and/or process of one or more processing or computing systems or similar devices that may manipulate and transform data represented as physical (e.g., electronic) quantities within a processing system's registers and memory into other data similarly represented as physical quantities within the processing system's registers or memories, or other such information storage, transmission or display devices. Furthermore, as used herein, a computing device includes one or more processing elements coupled with computer-readable memory that may be volatile or non-volatile memory or a combination thereof.

Embodiments of the invention may be implemented in one or a combination of hardware, firmware, and software. Embodiments of the invention may also be implemented as instructions stored on a machine-readable medium, which may be read and executed by at least one processor to perform the operations described herein. A machine-readable medium may include any mechanism for storing or transmitting information in a form readable by a machine (e.g., a computer). For example, a machine-readable medium may include read-only memory (ROM), random-access memory (RAM), magnetic disk storage media, optical storage media, flash-memory devices, and others.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a sigma-delta modulator to generate an output bit stream based on an input word;
multiply logic to multiply values of the output bit stream by a predetermined value; and
an offset adder to add the multiplied values of the output bit stream to an offset value for use in generating a divided-frequency signal.

2. The apparatus of claim 1 wherein a range of values of the input word is reduced proportionally by the inverse of the predetermined value allowing the sigma-delta modulator to operate within a more central portion of an operating range.

3. The apparatus of claim 2 wherein the range of values of the input word is halved when the multiply logic multiplies the output bit stream by two.

4. The apparatus of claim 2 wherein the sigma-delta modulator generates an output word of the output bit stream for each cycle of the divided-frequency signal, and
wherein the output bit stream comprises a pseudo-random sequence having an average value approximately equal to the input word.

5. The apparatus of claim 2 wherein the sigma-delta modulator is a first-order sigma-delta modulator that generates one-bit output words,
wherein the output words of the sigma-delta modulator have two possible values, and
wherein a range of values of the output words is reduced proportionally to the inverse of the predetermined value used by multiply logic.

6. The apparatus of claim 2 wherein the sigma-delta modulator is a second-order sigma-delta modulator that generates two-bit output words,
wherein the output words of the sigma-delta modulator have four possible values, and
wherein a range of values of the output words is reduced proportionally to the inverse of the predetermined value used by multiply logic.

7. The apparatus of claim 2 wherein the sigma-delta modulator is a third-order sigma-delta modulator that generates three-bit output words,
wherein the output words of the sigma-delta modulator have eight possible values, and
wherein a range of values of the output words is reduced proportionally to the inverse of the predetermined value used by multiply logic.

8. The apparatus of claim 2 further comprising a multi-modulus counter (MMC) to divide a radio-frequency (RF) signal based on a digital value provided by the offset adder to generate the divided-frequency signal,
wherein the multiply logic comprises a binary multiplier, and
wherein the offset adder is a digital offset adder to digitally add the multiplied values of the output bit stream to a digital offset value to generate the digital value for use by the MMC.

9. The apparatus of claim 8 wherein the circuitry is part of a phase-locked loop (PLL),
wherein the offset adder offsets the multiplied values of the output bit stream by the offset value to select one of a plurality of frequency bands, and
wherein the input word causes the PLL to tune to a frequency within the selected frequency band and allows the sigma-delta modulator to operate over the more central portion of the operating range.

10. The apparatus of claim 9 wherein the PLL comprises:
a phase-frequency detector (PFD) to produce control signals based on a phase difference between the divided-frequency signal and a fixed frequency reference signal;
a charge pump to receive the control signals from the PFD;
a loop filter to integrate an output of the charge pump and generate a control voltage; and
a voltage-controlled oscillator (VCO) to generate the RF signal based on the control voltage.

11. A phase-locked loop (PLL) comprising:
a sigma-delta modulator to generate an output bit stream based on an input word;
multiply logic to multiply values of the output bit stream by a predetermined value; and
an offset adder to add the multiplied values of the output bit stream to an offset value for use in generating a divided-frequency signal,
wherein the offset value selects one of a plurality of frequency bands by causing the offset adder to shift the multiplied output bit stream by the offset value,
wherein the input word causes the PLL to tune to a frequency within the selected frequency band, and
wherein a range of values of the input word is reduced proportionally by the inverse of the predetermined value allowing the sigma-delta modulator to operate within a more central portion of an operating range.

12. The PLL of claim 11 further comprising:
a multi-modulus counter (MMC) to receive a radio-frequency (RF) signal from an oscillator and divide the RF signal based on a value provided by the offset adder to generate the divided-frequency signal; and
a phase-frequency detector (PFD) to produce control signals to control the oscillator based on a phase difference between the divided-frequency signal and a fixed frequency reference signal.

13. The PLL of claim 12 further comprising:
a charge pump to receive the control signals from the PFD; and
a loop filter to integrate an output of the charge pump and generate a control voltage to control the oscillator,
wherein the oscillator is a voltage-controlled oscillator (VCO) to generate the RF signal based on the control voltage.

14. The PLL of claim 13 wherein the sigma-delta modulator generates an output word of the output bit stream for each cycle of the divided-frequency signal,
wherein the output bit stream comprises a pseudo-random sequence having an average value approximately equal to the input word,
wherein the multiply logic comprises a binary multiplier, and
wherein the offset adder is a digital offset adder to digitally add the multiplied values of the output bit stream to a digital offset value to generate a digital value for use by the MMC.

15. A method of generating an RF signal comprising:
generating an output bit stream based on an input word;
multiplying values of the output bit stream by a predetermined value;
adding the multiplied values of the output bit stream to an offset value for use in generating a divided-frequency signal; and
generating the RF signal from the divided-frequency signal.

16. The method of claim 15 further comprising:
receiving the offset value indicating a selected one of a plurality of frequency bands; and
receiving the input word indicating a frequency within the selected frequency band,
wherein a range of values of the input word is reduced proportionally by an inverse of the predetermined value allowing a sigma-delta modulator to operate within a more central portion of an operating range.

17. The method of claim 16 wherein the multiplying comprises multiplying the values of the output bit stream by two, and
wherein values of the input word are received over the more central portion of a range of the sigma-delta modulator.

18. A wireless communication device comprising:
front-end circuitry for communicating signals with one or more antennas; and
a signal generator to generate a radio-frequency (RF) signal for use by the front-end circuitry, the signal generator comprising:
a sigma-delta modulator to generate an output bit stream based on an input word;
multiply logic to multiply values of the output bit stream by a predetermined value; and
an offset adder to add the multiplied values of the output bit stream to an offset value for use in generating a divided-frequency signal.

19. The wireless communication device of claim 18 wherein the offset value selects one of a plurality of frequency bands by causing the offset adder to shift the multiplied output bit stream by the offset value,
wherein the input word allows the signal generator to tune to a frequency within the selected frequency band, and
wherein a range of values of the input word is reduced proportionally by the inverse of the predetermined value allowing the sigma-delta modulator to operate within a more central portion of an operating range.

20. The wireless communication device of claim 19 wherein the signal generator further comprises:
a multi-modulus counter (MMC) to receive the RF signal from an oscillator and divide the RF signal based on a value provided by the offset adder to generate the divided-frequency signal; and
a phase-frequency detector (PFD) to produce control signals for use in controlling the oscillator based on a phase difference between the divided-frequency signal and a fixed frequency reference signal.

21. The wireless communication device of claim 20 further comprising:
a controller to provide the offset value and the input word; and
baseband processing circuitry,
wherein when the wireless communication device operates as a receiver, the baseband processing circuitry processes signals downconverted by the front-end circuitry, and
wherein when the wireless communication device operates as a transmitter, the baseband processing circuitry provides signals to the front-end circuitry from transmission.

22. The wireless communication device of claim 19 wherein the range of values of the input word is halved when the multiply logic multiplies the output bit stream by two.

23. The wireless communication device of claim 19 wherein the sigma-delta modulator generates an output word of the output bit stream for each cycle of the divided-frequency signal, and
wherein the output bit stream comprises a pseudo-random sequence having an average value approximately equal to the input word.

24. The wireless communication device of claim 19 wherein the sigma-delta modulator is a first-order sigma-delta modulator that generates one-bit output words,
wherein the output words of the sigma-delta modulator have two possible values, and
wherein a range of values of the output words is reduced proportionally to the inverse of the predetermined value used by multiply logic.

25. The wireless communication device of claim 19 wherein the sigma-delta modulator is a second-order sigma-delta modulator that generates two-bit output words,
wherein the output words of the sigma-delta modulator have four possible values, and
wherein a range of values of the output words is reduced proportionally to the inverse of the predetermined value used by multiply logic.

26. The wireless communication device of claim 19 wherein the sigma-delta modulator is a third-order sigma-delta modulator that generates three-bit output words,
wherein the output words of the sigma-delta modulator have eight possible values, and
wherein a range of values of the output words is reduced proportionally to the inverse of the predetermined value used by multiply logic.
